(19) United States
(12) Patent Application Publication
(10) Pub. No.: US 2008/0054248 A1
(43) Pub. Date: Mar. 6, 2008

(54) VARIABLE PERIOD VARIABLE COMPOSITION SUPPERLATTICE AND DEVICES INCLUDING SAME

(76) Inventors: Christopher L. Chua, San Jose, CA (US); Zhihong Yang, Sunnyvale, CA (US); Noble Johnson, Menlo Park, CA (US)

Correspondence Address: JONATHAN A. SMALL;JAS IP CONSULTING, 343 2ND STREET, SUITE F, LOS ALTOS, CA, 94022, US

(21) Appl. No.: 11/470,569

(22) Filed: Sep. 6, 2006

(51) Int. Cl. H01L 31/00

(52) U.S. Cl. 257/14

(57) ABSTRACT

An optical semiconductor device such as a light emitting diode is formed on a transparent substrate having formed thereon a template layer, such as AlN, which is transparent to the wavelength of emission of the optical device. A variable period variable composition superlattice strain relief region is provided over the template layer such that the composition of the strain relief region approaches or matches the composition of the regions contiguous thereto. For example, the Al content of the strain relief region may be tailored to provide a stepped or gradual Aluminum content from template to active layer. Strain-induced cracking and defect density are reduced or eliminated.

### STATEMENT REGARDING FEDERALLY SPONSORED RESEARCH AND DEVELOPMENT

The U.S. Government has a fully paid-up license in this invention and the right in limited circumstances to require the patent owner(s) to license others on reasonable terms as provided for by the terms of contract number N66001-02-C-8017 awarded by the Defense Advanced Research Projects Agency, and contract number DAAH01-03-9-R003 sponsored by the U.S. Army Aviation and Missile Command.

### BACKGROUND OF THE INVENTION

1. Field of the Invention

The present invention is related generally to the field of semiconductor light emitting devices, and more specifically to an architecture for an improved high-Al content, low defect quantum well light emitting device formed directly on a final substrate.

2. Description of the Prior Art

In the III-V compound semiconductor family, the nitrides have been used to fabricate visible wavelength light emitting device active regions. They also exhibit a sufficiently high bandgap to produce devices capable of emitting light in the ultraviolet, for example at wavelengths between 290 and 400 nanometers. In particular, InAlGaN systems have been developed and implemented in visible and UV spectrum light emitting diodes (LEDs), such as disclosed in U.S. Pat. No. 6,875,627 to Bour et al., which is incorporated herein by reference. These devices are typically formed on an Al₂O₃ (sapphire) substrate, and comprise thereover a GaN:Si or AlGaN template layer, an AlGaN:Si/GaN superlattice structure for reducing optical leakage, an n-type electrode contact layer, a GaN n-type waveguide, an InGaN quantum well heterostructure active region, and a GaN p-type waveguide region. In addition, the complete device may also have deposited thereover a p-type AlGaN:Mg cladding layer and a capping layer below a p-type electrode.

While significant improvements have been made in device reliability, optical power output, and mode stability, the performance of the nitride-based lasers and light emitting diodes emitting in the ultraviolet (UV) is still inferior to that of their blue or violet counterparts. It is particularly true that for deep UV lasers and light emitting diodes operating at wavelengths below 340 nm, the nature of the substrate and template layer have a critical impact on the overall device performance. For example, differences in lattice constant between the substrate and the structural layers of the device significantly affects optical output and device lifetime. While Al₂O₃ (sapphire) as a substrate has numerous advantages, it is highly lattice mismatched to the structural layers of typical deep UV epi-layers. The prior art AlGaN template layer formed over the typical Al₂O₃ substrate mitigates the problem somewhat, but the resulting crystal quality of the high aluminum-containing structural layers in typical deep UV light-emitting devices utilizing these templates are still very poor.

The dislocation densities in AlGaN or AlN template layers on sapphire are typically in the mid 10⁹ to high 1010 cm⁻² range. As a consequence, the external quantum efficiencies of deep UV light emitting diodes in the 290 nm to 340 nm range are still well below the external quantum efficiencies for blue GaN-based LED structures. The high dislocation densities in typical AlGaN or AlN template layers on sapphire also pose significant problems for the light emitting device lifespan.

The emission wavelength of the light emitting diode is inversely related to the Al content in the multiple quantum well heterostructure (MQWH) active region of the device. Thus, in order to obtain shorter wavelength devices, such as those emitting in the UV, the Al content of the MQWH region must be increased over that found in devices emitting in the visible spectrum. However, increasing the Al content presents a number of structural and device performance problems discussed below.

Efforts to improve the quality of the LED structure in the ultraviolet range on AlₓGa₁₋ₓN/sapphire templates have presented significant challenges due to the high defect density of epitaxial layers formed over the AlGaN crystallographic template. In many cases, mechanical stresses lead to cracks in the heterostructure formed thereon. These issues are exacerbated when the Al content of layers formed above the AlGaN/sapphire system increases. Yet, as previously mentioned, an increased Al content (e.g., up to ˜50% in the MQWH active region of a 280 nm light emitting diode, and 60% to 70% in the surrounding AlGaN current and optical confinement layers) is required to obtain devices which emit in the UV.

Various groups have published approaches to dealing with these shortcomings. All references referred to herein, and specifically each of the following references, are incorporated herein by reference. For example, Han et al., Appl. Phys. Lett, Vol 78, 67 (2001), discuss the use of a single AlN interlayer formed at low temperatures to avoid strain development. This low-temperature AlN interlayer approach has proven unsuccessful in the case of heterostructure growth with high Al mole fractions. Nakamura et al., J. J. Appl. Phys., vol. 36, 1568 (1997) has suggested short period GaN/AlGaN superlattice layers as a way of extending the critical layer thickness of AlGaN films grown pseudomorphically on GaN/sapphire. But the average Al mole fraction in these AlGaN/GaN systems is at such a low level (˜10% or less) that it is not compatible with deep UV light emitting diodes. Chen et al., Appl. Phys. Lett., vol. 81, 4961 (2002) suggests an AlGaN/AlN layer as a dislocation filter for an AlGaN film on a AlGaN/sapphire template. But again, the AlGaN/sapphire template presents the aforementioned series resistance problem. And Wong et al. in U.S. patent application Ser. No. 11/356,769, filed on Feb. 17, 2006, proposes a GaN/AlN superlattice formed between the GaN template layer and the MQWH active region. But again, the GaN template layer must be removed prior to light output for such a device.

There is a need for a UV light emitting device apparatus with improved operation characteristics. Accordingly, there is a need for a method and structure facilitating a high Al content MQWH active region with reduced cracking and related damage.

### SUMMARY OF THE INVENTION

The present invention is directed to facilitating the growth of high aluminum content heterostructure active regions on an initial AlGaN surface for UV light emitting devices such as light emitting diodes (LED) and laser diodes (LD). The initial AlGaN surface can, for example be an AlN or a GaN template on sapphire, an AlGaN template on silicon carbide, or a bulk AlN or GaN substrate. More specifically, the present invention is directed to systems and methods for providing an improved transition from an initial AlₓGa₁₋ₓN surface (where 0≦x≦1) to a high-Al content MQWH active region. According to one embodiment of the present invention, a structure is formed beginning with a sapphire substrate on which is deposited an AlN template layer. A strain relief region is next formed over the template layer such that the average Al content of the strain region varies over its thickness. For example, the average Al content may go from a relatively high value, such as 80% or higher, adjacent the template layer to a relatively lower value, such as 60% or lower, adjacent the MQWH region. In this way, the average Al content of the strain relief region more closely matches the Al content of the regions contiguous thereto.

According to one aspect of the invention, the strain relief region is comprised of a variable period superlattice. The variable period superlattice may be comprised of two or more subsections of alternating layers of AlN of a first thickness and GaN of a second thickness. The thickness of the AlN layer decreases from subsection to subsection along the height of the strain relief region. The effect of this varying thickness of AlN is to vary the average Al content of that subsection. In this way, the average Al content may be decreased from one subsection to the next until an uppermost layer has the desired Al content. In one embodiment, the strain relief region comprises two such subsections. In another embodiment of the present invention the strain relief layer comprises more than two subsections.

According to another aspect of the invention, the variable period superlattice may be comprised of a continuum of alternating layers of AlN and GaN. The thicknesses of the AlN layers gradually decrease from one AlN/GaN pair to the next. In this way, the average Al content of the strain relief layer decreases from bottom to top, such that the bottom portion thereof matches (or approaches) the Al content of a layer contiguous thereto (e.g., the template layer), and the average Al content of the top portion matches (or approaches) the Al content of a layer contiguous thereto (e.g., the MQWH) so that an improved lattice match is provided at the region interfaces.

According to still another aspect of the invention, a pure AlN layer is deposited over the AlN template layer prior to deposition of the strain relief region. This AlN interface layer is generally thicker than the AlN layers of the strain relief region, and provides a transition from the template layer to the strain relief region.

Thus, in one embodiment, the present invention provides a strain relief region for a light emitting semiconductor device, said strain relief region formed above a substrate and below a multiple quantum well heterostructure active region, the multiple quantum well heterostructure active region composed in part of a first element so as to have an average composition of the first element, said strain relief region comprising a plurality of groups of at least two layers, at least one layer of each said group comprised at least in part of the first element such that each group has an average concentration of the first element, the average concentration of the first element varying from group to group from a first concentration to a second concentration along the height of the strain relief region such that the average concentration of the first element in the group nearest the multiple quantum well heterostructure active region approaches the concentration of the first element in said multiple quantum well heterostructure active region. A number of variation of this embodiment are also provided.

In another embodiment, the present invention provides a strain relief region for a light emitting semiconductor device, said strain relief region formed above a first semiconductor layer and below a second semiconductor layer, the bandgap of the first semiconductor layer being different from the bandgap of the second semiconductor layer, said strain relief region comprising a plurality of groups of layers, each group comprising a periodic ordering of layers, the average bandgap of the group closest to the first semiconductor layer being closer to the bandgap of the first semiconductor layer than to the bandgap of the second semiconductor layer. A number of variation of this embodiment are also provided.

Thus, the strain relief region according to the present invention provides a transition between a starting surface (such as a substrate, possibly with a template layer formed thereon) and the MQWH. Strain-induced cracking and defect density are reduced or eliminated.

The above is a summary of a number of the unique aspects, features, and advantages of the present invention. However, this summary is not exhaustive. Thus, these and other aspects, features, and advantages of the present invention will become more apparent from the following detailed description and the appended drawings, when considered in light of the claims provided herein.

### BRIEF DESCRIPTION OF THE DRAWINGS

In the drawings appended hereto like reference numerals denote like elements between the various drawings. While illustrative, the drawings are not drawn to scale. In the drawings:

FIG. 1 is a cross-sectional illustration of the general architecture of a heterostructure AlGaInN light emitting device structure in accordance with the present invention.

FIG. 2 is an illustration of the general architecture of a variable period variable composition superlattice strain relief region, and surrounding layers, according to one aspect of the present invention.

FIG. 3 is a cross-sectional illustration of an exemplary light emitting diode structure in accordance with the present invention.

FIG. 4 is a graphical depiction of a variable period variable composition strain relief region comprising two short-period groups of AlN/GaN layer pairs, illustrating the two respective periods of said groups.

FIG. 5 is an x-ray spectrum of a variable period variable composition superlattice grown on a reference GaN sample.

FIG. 6 is cross sectional view of a complete LED structure fabricated according to the present invention.

FIG. 7 is a comparison of the performance of an LED utilizing the variable period variable composition strain relief region according to the present invention to the performance of a prior art LED of identical structure with the exception of a GaN/AlN single-period superlattice strain relief region.

FIG. 8 is an optical micrograph of the top-most surface of an as-grown LED heterostructure manufactured according to the present invention.

### DETAILED DESCRIPTION OF THE INVENTION

With reference now to FIG. 1, there is shown therein the general architecture of a heterostructure AlGaInN light emitting device structure 10 in accordance with the present invention. Diode structure 10 comprises a substrate 12. According to one embodiment of the present invention, substrate 12 may be Al₂O₃ (sapphire) on which is formed a template layer 14. As described further below, other substrates such as Silicon Carbide, bulk AlN, or bulk GaN may be employed. Template layer 14 may be AlN, but may also be AlₓGa₁₋ₓN where x is not equal to 1. In some cases, template layer 14 is not necessary and is absent. Formed thereon is an optional interface layer 16. In the embodiment in which template layer 14 is AlN, interface layer 16, if present, is preferably also AlN.

Formed above interface layer 16 is variable period variable composition superlattice strain relief region 18 comprising a number of layer pairs, such as AlN/GaN, described further below. Additional layers, such as AlGaN:Si buffer layer 20, n-contact layer 21, AlGaN/AlGaN:Si superlattice n-strain layer 22 (which allows for increased cladding thickness and hence reduced optical leakage of subsequent layers), AlGaN:Si n-cladding (index guiding) layer 24, and active MQWH layer 26 (such as InAlGaN) may then be formed thereover.

Subsequent layer such as the following may also be formed on MQWH layer 26: an AlGaN:Mg p-cladding (index guiding) layer 28, an AlGaN:Mg buffer layer 30, an AlGaN/AlGaN:Mg p-strain layer 32, and a GaN:Mg capping layer 34. The aforementioned layers may be formed by any method know in the art, including but not limited to methods described in U.S. Pat. No. 6,875,627 to Bour et al., which is incorporated by reference herein. It will be appreciated that a complete device will also include electrodes, not shown, as well as other similar or alternative devices formed in the manner of an array in appropriate embodiments.

Prior art devices comprising a template layer may include a material such as GaN for the template which must be removed prior to device operation, or which result in significant layer cracking and/or high defect density. Other prior art devices that comprise a high Al-content layer grown directly on an AlN template layer will exhibit high strain due to lattice mismatch between the two adjacent materials. One aspect of the present invention addresses these problems through the introduction of a transition layer between an initial growth surface and a high Al containing active layer, the transition layer comprising of a novel variable period variable composition superlattice strain relief region.

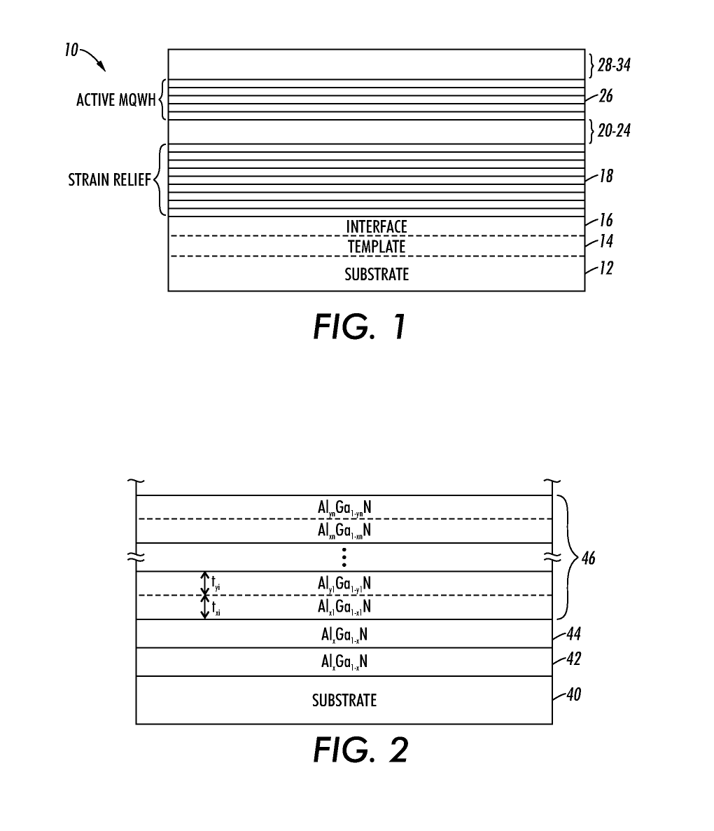

FIG. 2 is an illustration of the general architecture of a variable period variable composition superlattice strain relief region, and surrounding layers, according to one aspect of the present invention. In one embodiment, a layer 42, typically AlₓGa₁₋ₓN (0≦x≦1), is formed on substrate 40. While layer 42 is often referred to as a template layer, the combination of substrate 40 and layer 42 together form the template for the growth of additional layers. Over this template a variable period variable composition superlattice strain relief region 46 is formed which acts as a transition from the template to the MQWH active region, gradually or in step-wise fashion transitioning from the aluminum content of the template to the aluminum content of the active region.

As shown in FIG. 2, strain relief region 46 consists of a plurality of pairs of layers of the form AlₓᵢGa₁₋ₓᵢN, with a thickness tₓᵢ, and Al_{yi}Ga_{1-yi}N, with a thickness t_{yi}, where 0<x≦1 and 0<y≦1. The plurality of layers are arranged in i groups where 2≦i≦n. Thus, xi represents the aluminum content in a first layer of a layer pair of the i^{th} group, and yi represents the aluminum content in a second layer of that layer pair in the i^{th} group. The average aluminum content of each group, i, of layer 46 can be determined as follows:

$$\frac{{t}_{xi} {x}_{i} + {t}_{yi} {y}_{i}}{{t}_{xi} + {t}_{yi}}$$

Accordingly, by varying xi, yi, tₓᵢ and t_{yi}, the average aluminum content of each group of layer pairs can be controlled. Variable periodicity is achieved by varying the thickness tₓᵢ and t_{yi} for different periods i, while variable composition is achieved by varying the compositions xi and yi for different periods i.

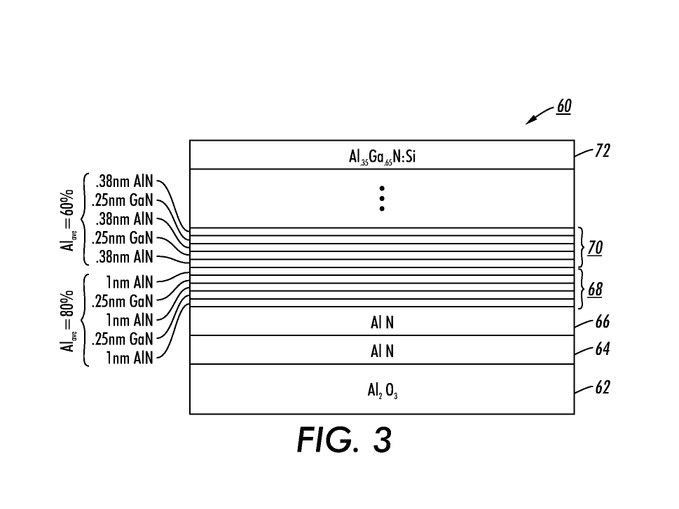

With reference now to FIG. 3, in order to demonstrate the concept forming the present invention, we grew a light emitting diode (LED) structure 60 utilizing a two-group variable period variable composition superlattice strain relief region. We chose an AlN/GaN superlattice design with fixed composition (xi=1 and yi=0) for all periods. The LED is designed to operate at a wavelength λ of about 325 nm, requiring an active region heterostructure Al composition of about 35%. The template layer 64 was a 1 μm thick epitaxial layer of AlN grown on a sapphire substrate 62 (in other words, with reference to FIG. 2, x=1 in layer 42). A 25-30 nm thick AlN interface layer 66 was formed over template layer 64.

A first group 68 of 40 short period superlattice layer pairs of AlN/GaN were then formed over layer 64. We chose a first region average Al composition of 80%, and a second region average Al content of 60%, and tailored the layer thicknesses for xi=1 and yi=0 to produce these compositions as follows. In the first group 68 the thicknesses were tₓᵢ=1 nm, t_{yi}=0.25 nm for 40 pairs (i=1 to 40). In the second group 70 the thicknesses were tₓᵢ=0.38 nm, t_{yi}=0.25 nm for the remaining 40 pairs (i=41 to 80). This produced an AlN/GaN short period superlattice with an average Al composition of 80% for the first 40 pairs at the template end of the superlattice and 60% for the second 40 pairs at the heterostructure end. The thicknesses of the individual layers of the variable period superlattice, tₓᵢ and t_{yi}, are made very thin to minimize strain due to lattice mismatch.

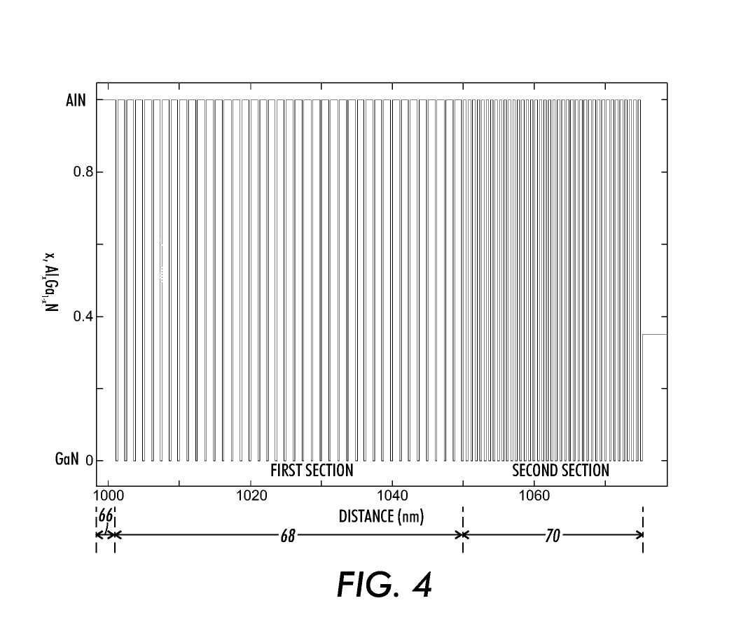

FIG. 4 is a graphical depiction of groups 68, 70 of the aforementioned LED 60, illustrating the two respective periods of said groups. As will be appreciated from FIG. 4, while the number of layer pairs in each group is the same, the difference in layer thickness results in group 68 being thicker than group 70.

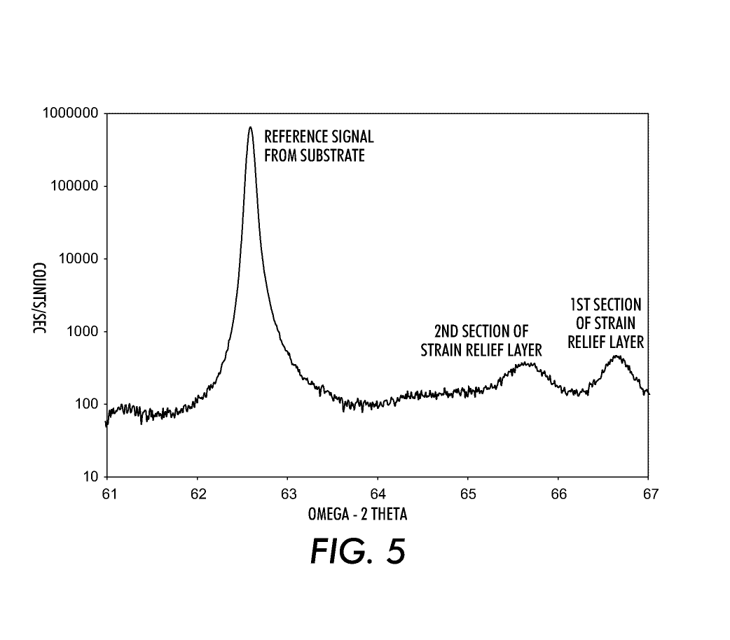

Referring next to FIG. 5, the graph shows an x-ray spectrum taken from a sample comprising the variable period superlattice of FIG. 3 grown on a GaN on sapphire template. The GaN template produces a large main peak that is used as reference. The two side peaks come from regions 68 and 70 of FIG. 3. Region 70 of FIG. 3 has a lower average Al content than region 68, so it corresponds to the peak near the GaN reference peak. The X-ray peak occurring at the higher omega-2 theta angle comes from region 68. The two peaks correspond to the two different average Al contents within the two sections of the superlattice. Variable period superlattice with more than two different periods will have more than two X-ray peaks. Similar test samples comprising single period superlattice strain relief layers such as those employed in the aforementioned U.S. patent application Ser. No. 11/356,769 will produce one peak.

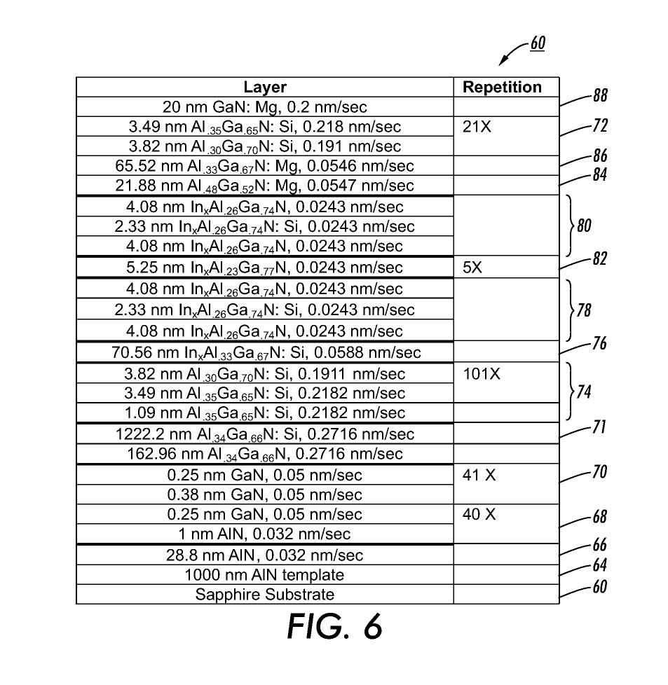

With reference to FIG. 6, a complete LED structure 60 according to the present invention is illustrated in cross section. In addition to the previously described elements, the structure incorporates n contact layer 71, n-cladding layer 74, n waveguide 76, barrier layers 78 (10.49 nm), 80 (89.19 nm), with quantum well 82 (5.25 nm) therebetween, tunnel barrier layer 84, and p waveguide and contact 86, 88. Some of these layers such as waveguide layers 76 and 84 allow the LED design to be easily extendable to laser diodes but do not perform actual waveguiding functions when the device is operated in LED mode.

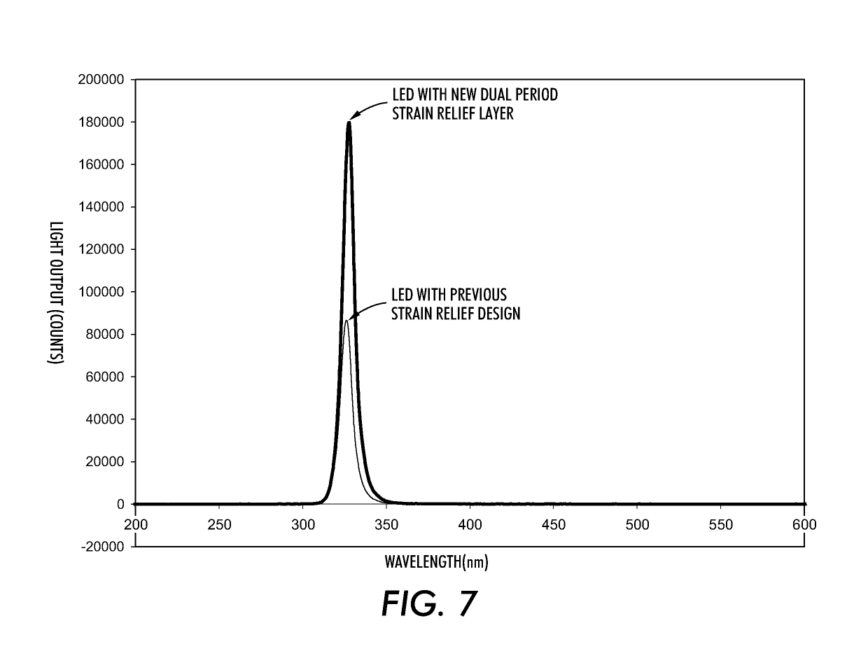

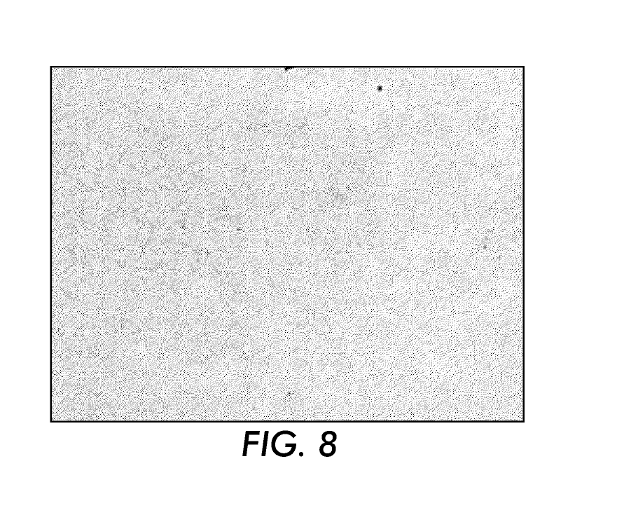

Referring now to FIG. 7, the performance of an LED utilizing the variable period variable composition superlattice strain relief region according to the present invention is compared to a prior art LED of identical structure with the exception of a GaN/AlN single-period superlattice strain relief region. As can be seen, the light output of the LED incorporating the variable period variable composition superlattice strain relief region according to the present invention demonstrated significantly brighter optical output than the LED grown on prior art single period binary superlattice strain relief layers. From this we conclude that devices incorporating the strain relief region taught herein benefit from enhanced optical output, due to the more gradual transition in Al content provided by the strain relief structure.

FIG. 8 shows an optical micrograph of the top-most surface of an as-grown LED heterostructure manufactured with the variable period variable composition strain relief region of the present invention. As can be seen, a substantially crack-free surface is produced.

It will be appreciated that while the foregoing describes an embodiment of the present invention utilizing a two-group, step-wise superlattice design, the concept extends to include many different region profiles, such as three or more groupings (e.g., with an average composition of approximately 80%, 70% and 60%, respectively), or continuously varying composition profiles, varying linearly, parabolically, exponentially or otherwise, each providing a different transition profile for the Al content in the region. For example, a three step superlattice would have three layers per period, each layer with aluminum contents of, say, xi, yi, zi and thicknesses txi, tyi, and txi for period i. A three-group superlattice would transition step-wise, with for example two steps per period, from the Al content matching or approaching that of the transition layer to the Al content matching or approaching that of the active region. The abrupt transition between layers within each period can also be replaced with a transition layer whose Al content varies continuously from a starting composition near that of the starting layer to an ending composition near that of the adjacent layer. The general case would be a strain relief layer comprising a continuously varying composition profile starting with a composition close to that of the initial surface and ending with an Al composition close to that of the heterostructure active layer. The continuous composition profile can be linear, parabolic, or can consist of curves with multiple points of inflection.

It is also common to add a small amount of Indium in the aluminum containing alloys to improve structural quality. An example of a structure utilizing Indium quaternary alloys in the structural layers has already been described in FIG. 6. Indium, typically at a concentration of about 1% to 2%, can also be added to some or all of the layers within the strain relief layer.

Furthermore, while the discussion above has been focused towards multiple quantum well active regions, it will be appreciated by one skilled in the art that other types of light-emitting active regions such as double heterojunction (DH), homojunction, quantum wire, active regions incorporating nanometer scale compositional inhomogeneities (NCl), and single quantum well active regions could also be employed. Moreover, while the discussion has been focused on light emitting diodes (LEDs), it will be appreciated by one skilled in the art that the structures and methods described also applies to other types of light emitting devices such as laser diodes and pump lasers.

Thus, while a plurality of preferred exemplary embodiments have been presented in the foregoing detailed description, it should be understood that a vast number of variations exist, and these preferred exemplary embodiments are merely representative examples, and are not intended to limit the scope, applicability or configuration of the invention in any way. Rather, the foregoing detailed description provides those of ordinary skill in the art with a convenient guide for implementation of the invention, and contemplates that various changes in the functions and arrangements of the described embodiments may be made without departing from the spirit and scope of the invention defined by the claims thereto.

What is claimed is:

1. A strain relief region for a light emitting semiconductor device, said strain relief region formed above a substrate and below an active region, the active region composed in part of a first element so as to have an average composition of the first element, said strain relief region comprising:
a plurality of groups of at least two layers, at least one layer of each said group comprised at least in part of the first element such that each group has an average concentration of the first element, the average concentration of the first element varying from group to group from a first concentration to a second concentration along the height of the strain relief region such that the average concentration of the first element in the group nearest the multiple quantum well heterostructure active region approaches the concentration of the first element in said multiple quantum well heterostructure active region.

2. The strain relief region of claim 1, wherein the average concentration of the first element in the group nearest the multiple quantum well heterostructure active region is said second concentration, and further wherein said first concentration is greater than said second concentration.

3. The strain relief region of claim 1, wherein for each group the different layers comprising that group periodically repeat in order a plurality of times

4. The strain relief layer of claim 3, wherein for each group the concentration of the first element in each of the at least one layers in that group is the same.

5. The strain relief layer of claim 3, wherein the average concentration of the first element varies linearly from group to group along the height of the strain relief region.

6. A strain relief region for a light emitting semiconductor device, said strain relief region formed over a structural region having a template surface and below a active layer, at least one of the structural region and the active layer being composed in part of a first element, said strain relief region comprising:
a plurality of groups of layers, each at least one layer within each said group comprised at least in part of the first element, the average concentration of the first element being higher in the group closest to the template layer relative to all groups in the strain relief region, and the average concentration of the first element being lower in the group closest to the multiple quantum well heterostructure active region relative to all groups in the strain relief region.

7. The strain relief region of claim 6, wherein the strain relief region is comprised of a plurality of groups of layers, each group comprising at least one layer sub-group, a first layer of the layer sub-group comprised at least in part of the first element and a second layer of the layer sub-group not including the first element.

8. The strain relief region of claim 7, wherein for each group the concentration of the first element is the same for all said first layers with said group.

9. The strain relief region of claim 8, wherein each group has an average concentration of the first element, the average concentration of the first element being higher in the group closest to the structural region relative to all groups in the strain relief region, and the average concentration of the first element being lower in the group closest to the multiple quantum well heterostructure active region relative to all groups in the strain relief region.

10. The strain relief region of claim 7, wherein the number of groups is two.

11. The strain relief region of claim 10, wherein the number of layers in each sub-group is two.

12. The strain relief region of claim 7, wherein the average concentration of the first element in the group closest to the template layer is in the range of 70-85%, and the average concentration of the first element in the group closest to the multiple quantum well heterostructure active region is in the range of 50-65%.

13. The strain relief region of claim 6, wherein the first element is aluminum.

14. The strain relief region of claim 6, wherein the average concentration of the first element varies linearly from group to group along the elevation of the strain relief layer.

15. The strain relief region of claim 7, wherein the structural region is composed of AlN, the active region has an aluminum concentration between 30% and 40%, the average aluminum concentration in the group closest to the template layer is in the range of 70-85%, and the average aluminum concentration in the group closest to the multiple quantum well heterostructure active region is in the range of 50-65%.

16. A strain relief region for a light emitting semiconductor device, said strain relief region formed on a substrate having a template layer formed thereon and below a active region, comprising:
at least two groups of layer pairs, each layer pair comprising a first layer of composition
In_{z}AlₓGa_{1-x-z}N where 0<x≦1, 0≦z<1
and a second of composition
InₚAl_{y}Ga_{1-y-p}N where 0<y≦1, 0<p≦1
a first of said groups proximate said template layer having an average aluminum content equal to or approaching the aluminum content of said template layer; and
a second of said groups proximate said multiple quantum well heterostructure active region having an average aluminum content equal to or approaching the aluminum content of said multiple quantum well heterostructure active region.

17. A strain relief region for a light emitting semiconductor device, said strain relief region formed above a first semiconductor layer and below a second semiconductor layer, the bandgap of the first semiconductor layer being different from the bandgap of the second semiconductor layer, said strain relief region comprising:
a plurality of groups of layers, each group comprising a periodic ordering of layers, the average bandgap of the group closest to the first semiconductor layer being closer to the bandgap of the first semiconductor layer than to the bandgap of the second semiconductor layer.

18. The strain relief region of claim 17, wherein the light emitting device produces light in the wavelength range of between 250 nm and 360 nm.

19. The strain relief region of claim 17, wherein said strain relief region is formed over a template layer comprising AlₓGa₁₋ₓN, where 0≦x≦1.

20. The strain relief region of claim 17, wherein the light emitting device is a laser.

21. The strain relief region of claim 17, wherein the light emitting device is a light emitting diode.

22. A semiconductor light emitting device, comprising:
an Al₂O₃ substrate;
an InₖAlₓGa₁₋ₓ₋ₖN template layer formed over said substrate;
a strain relief region formed over said template layer;
a active region having a composition In_{z}Al_{y}Ga_{1-y-z}N, formed over said strain relief region; and
said strain relief region comprising a plurality of groups of layer pairs, a first of each said layer pair having a composition InᵣAlₛGa₁₋ₛ₋ᵣN, and a second of each said layer pair having a composition In_{q}AlₜGa_{1-t-q}N, and wherein each group has an average aluminum concentration, the average aluminum concentration of the group proximate the template layer approaching or equal to x, and the average aluminum concentration of the group proximate the quantum well heterostructure active region approaching or equal to y.

23. The semiconductor light emitting device of claim 22, further comprising an interface layer formed above said template layer and below said strain relief region, said interface layer having a composition matching the composition of said template layer.
